(19) United States
(12) Patent Application Publication
(10) Pub. No.: US 2024/0341205 A1
(43) Pub. Date: Oct. 10, 2024

(54) Phase Change Material In An Electronic Switch Having A Flat Profile

(71) Applicant: Taiwan Semiconductor Manufacturing Company, Ltd., Hsin-Chu (TW)

(72) Inventor: Tsung-Hsueh Yang, Taichung City (TW)

(21) Appl. No.: 18/340,253

(22) Filed: Jun. 23, 2023

Related U.S. Application Data
(60) Provisional application No. 63/494,924, filed on Apr. 7, 2023.

(51) Int. Cl. H10N 70/00

(52) U.S. Cl. CPC H10N 70/823; H10N 70/023; H10N 70/026; H10N 70/8613; H10N 70/231; H10N 70/841; H10N 70/8828

(57) ABSTRACT

A radio frequency (RF) switch includes a first conductive component and a second conductive component each disposed over a material layer in a cross-sectional side view. The RF switch includes a heater component disposed over the material layer in the cross-sectional side view. A segment of the heater component is disposed between the first conductive component and the second conductive component in the cross-sectional side view. An upper surface of the heater component is less elevated vertically than an upper surface of the first conductive component or the second conductive component in the cross-sectional side view. The RF switch includes a phase change material (PCM) disposed over the segment of the heater component and at least partially over the first conductive component and the second conductive component. A resistivity of the PCM changes in response to an application of heat. The heat is produced by the heater component.

### PRIORITY DATA

The present application is a utility patent application of provisional U.S. patent application 63/494,924, filed on Apr. 7, 2023, entitled “Radio Frequency Switch With Flat Phase Change Material”, the disclosure of which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

However, as the scaling down process continues, certain challenges may arise. For example, IC components may be implemented as electronic switches to control the transmission of electrical signals. When devices had larger sizes in older technology nodes, the performance of the electronic switches was not overly sensitive to the geometric shapes of the electronic switches. However, as device sizes shrink, the shapes of the electronic switches may begin to negatively impact the performance of the electronic switches. For example, a step height in an electronic switch (e.g., due to a part of the electronic switch being formed in a bent manner) may degrade the performance and/or the lifetime of the electronic switch.

Therefore, although existing IC devices and their methods of fabrication have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1A illustrates a three-dimensional perspective view of a FinFET device.

FIG. 1B illustrates a top view of a FinFET device.

FIG. 1C illustrates a three-dimensional perspective view of a multi-channel gate-all-around (GAA) device.

FIGS. 2-20 illustrate a series of cross-sectional side views of an IC device at various stages of fabrication according to embodiments of the present disclosure.

FIG. 21 illustrates a top view of a portion of an IC device according to embodiments of the present disclosure.

FIG. 22 illustrates a cross-sectional side view of an IC device at a stage of fabrication according to embodiments of the present disclosure.

FIG. 23 illustrates an integrated circuit fabrication system according to various aspects of the present disclosure.

FIG. 24 is a flowchart illustrating a method of fabricating an IC device according to various aspects of the present disclosure.

### DETAILED DESCRIPTION

The following disclosure provides many different embodiments, or examples, for implementing unique features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to an electronic switch, and more particularly, to an electronic switch that is implemented at least in part using a phase change material (PCM), where the PCM has a substantially flat profile. For example, through the performance of unique fabrication process flows according to various embodiments of the present disclosure, the resulting PCM herein may achieve a shape that includes a substantially flat upper surface and/or a substantially flat bottom surface. Such a flat profile of the PCM avoids (or at least significantly reduces) the presence of a step height that exists in conventional electronic switches. In that regard, the fabrication process flow used to form conventional electronic switches typically lead to a step height in the PCM, which may be a result of the PCM being formed in a “bent” manner. When IC device sizes were greater in older IC fabrication technology generations, such a step height was not a significant concern, as its impact on device performance and/or lifetime was minimal. However, as device sizes shrink, the existence of such a step height in the PCM may lead to a clustering of certain types of atoms (e.g., a clustering of germanium atoms) in regions of the PCM at or near the step height. When this occurs, the material composition of the PCM is effectively altered, which may adversely impact its intended functionality as a switchable component in the electronic switch. Furthermore, the lifetime of the PCM may also be shortened, and the electronic switch may experience premature failure.

To address these issues discussed above, the present disclosure utilizes unique fabrication process flows to ensure that the resulting PCM can achieve a substantially flat shape (e.g., a substantially flat top surface and a substantially flat bottom surface), which eliminates or at least reduces the step height that is found in the PCM of conventional electronic switches. Consequently, the resulting PCM may be free of the undesirable clusters that are typically found in conventional devices. Therefore, the performance and/or longevity of the electronic switches (where the PCM is implemented) may be improved.

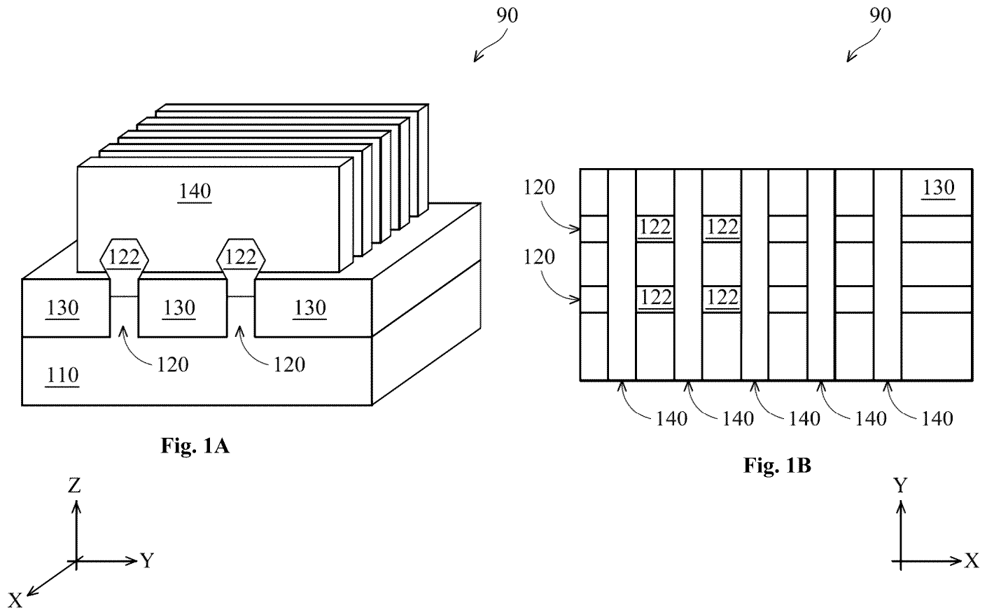

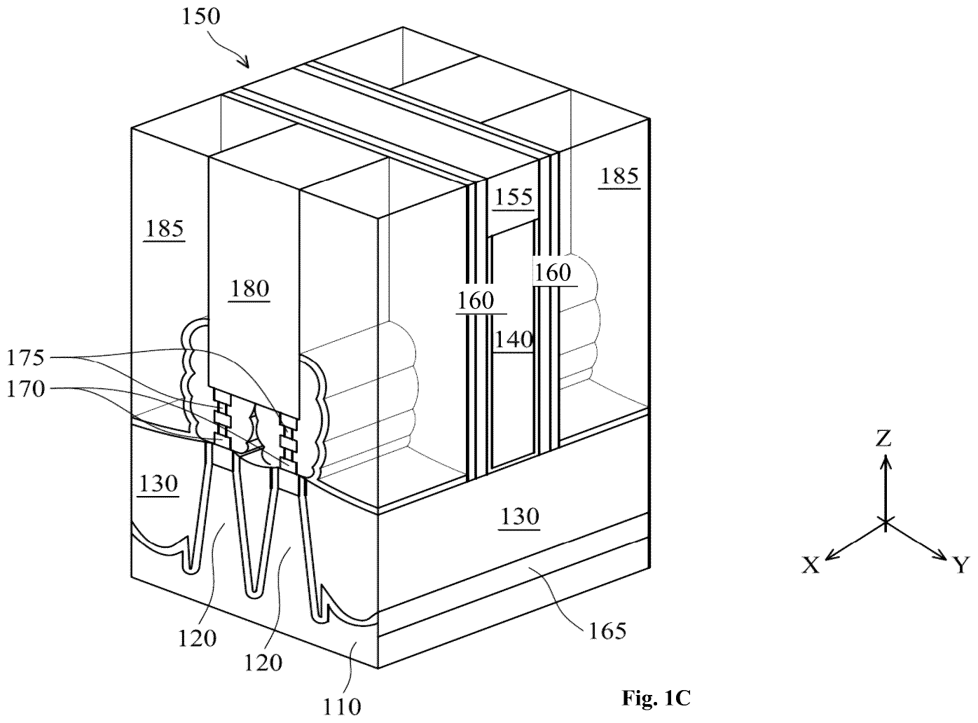

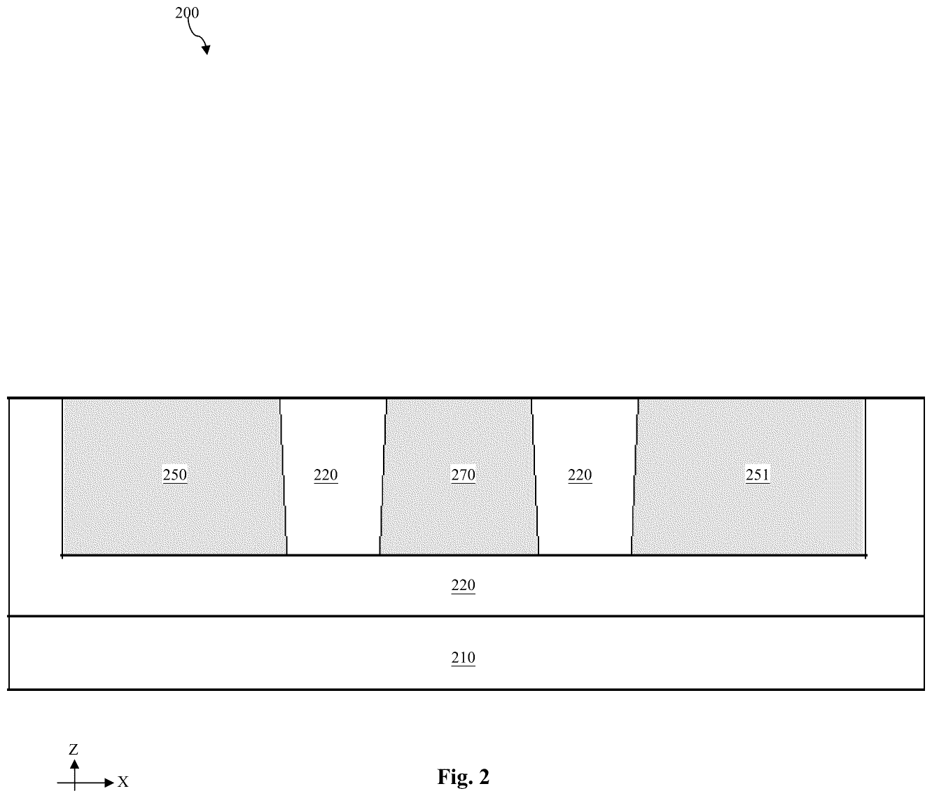

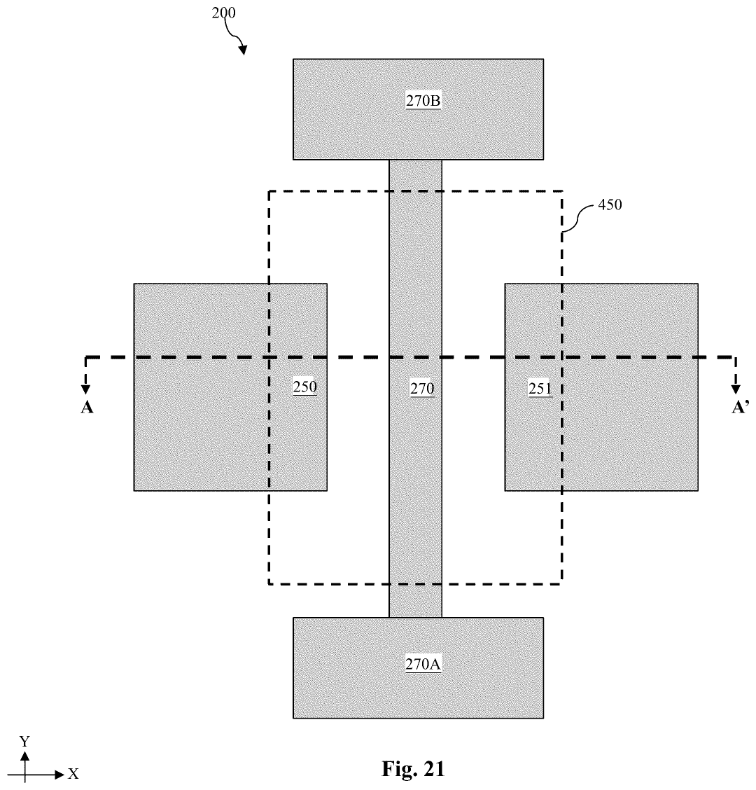

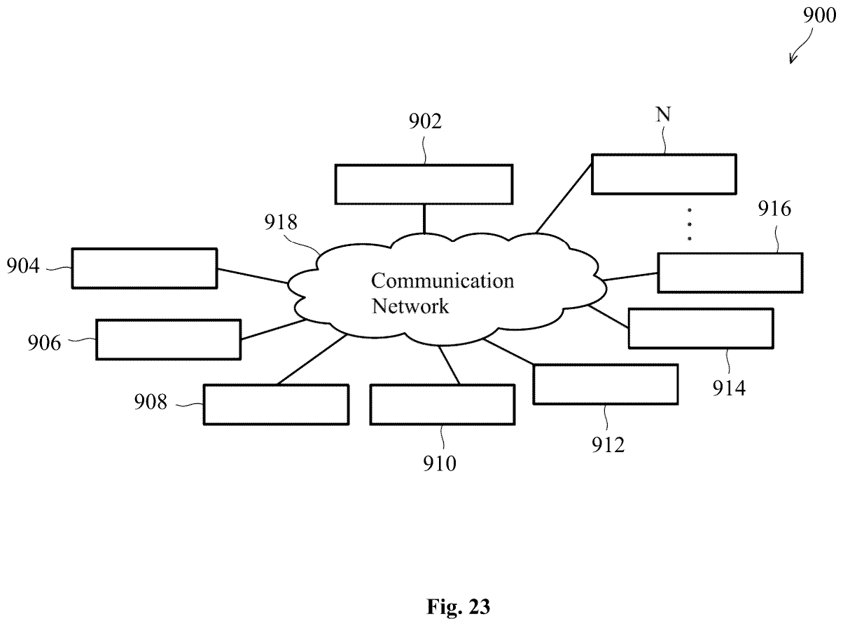

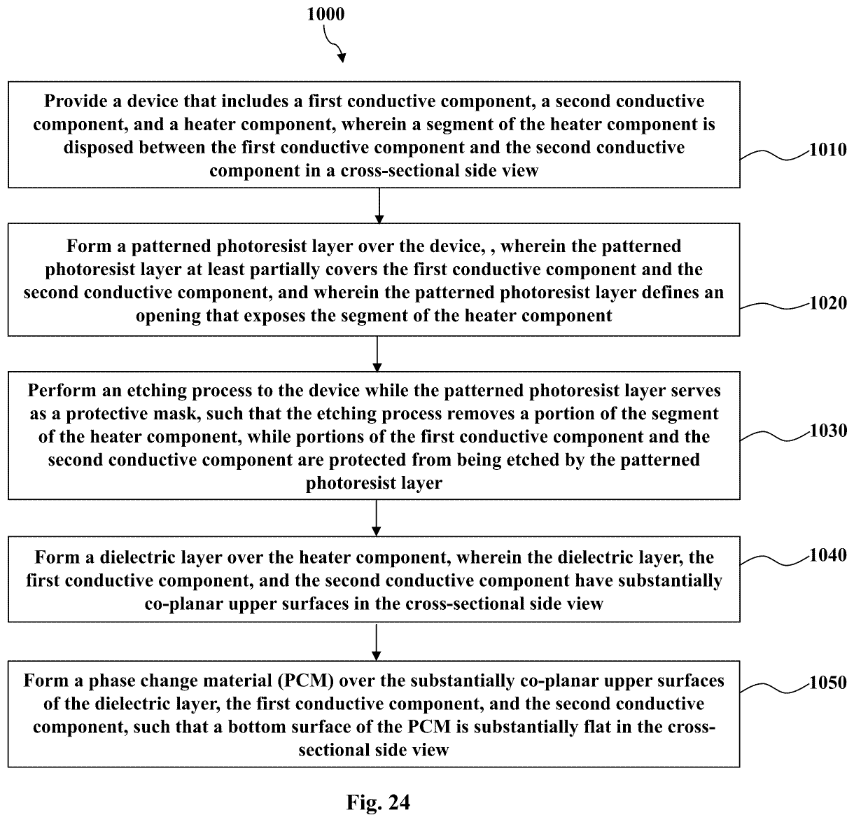

The various aspects of the present disclosure will now be discussed below with reference to FIGS. 1A, 1B, 1C and 2-24. In more detail, FIGS. 1A-B illustrate an example FinFET device, and FIG. 1C illustrates an example GAA device. FIGS. 2-20 and 22 illustrate cross-sectional side views of an IC device at various stages of fabrication according to embodiments of the present disclosure. FIG. 21 illustrates a planar top view of a portion of an IC device. FIG. 23 illustrates a semiconductor fabrication system. FIG. 24 illustrates a flowchart of a method of fabricating an IC device according to various aspects of the present disclosure.

Referring now to FIGS. 1A and 1B, a three-dimensional perspective view and a top view of a portion of an Integrated Circuit (IC) device 90 are illustrated, respectively. The IC device 90 is implemented using field-effect transistors (FETs) such as three-dimensional fin-line FETs (FinFETs). FinFET devices have semiconductor fin structures that protrude vertically out of a substrate. The fin structures are active regions, from which source/drain region(s) and/or channel regions are formed. Source/drain region(s) may refer to a source or a drain, individually or collectively dependent upon the context. A source/drain region may also refer to a region that provides a source and/or drain for multiple devices. The gate structures partially wrap around the fin structures. In recent years, FinFET devices have gained popularity due to their enhanced performance compared to conventional planar transistors.

As shown in FIG. 1A, the IC device 90 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions 120 are formed on the substrate 110. The active regions 120 may include elongated fin-like structures that protrude upwardly out of the substrate 110. As such, the active regions 120 may be interchangeably referred to as fin structures 120 or fins 120 hereinafter. The fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 90 also includes source/drain components 122 formed over the fin structures 120. The source/drain components 122 may include epi-layers that are epitaxially grown on the fin structures 120. The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fin structures 120 on three sides in a channel region of each fin 120. In other words, the gate structures 140 each wrap around a plurality of fin structures 120. The gate structures 140 may be dummy gate structures (e.g., containing an oxide gate dielectric and a polysilicon gate electrode), or they may be High-k metal gate (HKMG) structures that contain a high-k gate dielectric and a metal gate electrode, where the HKMG structures are formed by replacing the dummy gate structures. Though not depicted herein, the gate structure 140 may include additional material layers, such as an interfacial layer over the fin structures 120, a capping layer, other suitable layers, or combinations thereof.

Referring to FIGS. 1A-1B, multiple fin structures 120 are each oriented lengthwise along the X-direction, and multiple gate structure 140 are each oriented lengthwise along the Y-direction, i.e., generally perpendicular to the fin structures 120. In many embodiments, the IC device 90 includes additional features such as gate spacers disposed along sidewalls of the gate structures 140, hard mask layer(s) disposed over the gate structures 140, and numerous other features.

FIG. 1C illustrates a three-dimensional perspective view of an example multi-channel gate-all-around (GAA) device 150. GAA devices have multiple elongated nano-structure channels that may be implemented as nano-tubes, nano-sheets, or nano-wires. For reasons of consistency and clarity, similar components in FIG. 1C and FIGS. 1A-1B will be labeled the same. For example, active regions such as fin structures 120 rise vertically upwards out of the substrate 110 in the Z-direction. The isolation structures 130 provide electrical separation between the fin structures 120. The gate structure 140 is located over the fin structures 120 and over the isolation structures 130. A mask 155 is located over the gate structure 140, and gate spacers 160 are located on sidewalls of the gate structure 140. A capping layer 165 is formed over the fin structures 120 to protect the fin structures 120 from oxidation during the forming of the isolation structures 130.

A plurality of nano-structures 170 is disposed over each of the fin structures 120. The nano-structures 170 may include nano-sheets, nano-tubes, or nano-wires, or some other type of nano-structure that extends horizontally in the X-direction. Portions of the nano-structures 170 under the gate structure 140 may serve as the channels of the GAA device 150. Dielectric inner spacers 175 may be disposed between the nano-structures 170. In addition, although not illustrated for reasons of simplicity, each stack of the nano-structures 170 may be wrapped around circumferentially by a gate dielectric as well as a gate electrode. In the illustrated embodiment, the portions of the nano-structures 170 outside the gate structure 140 may serve as the source/drain features of the GAA device 150. However, in some embodiments, continuous source/drain features may be epitaxially grown over portions of the fin structures 120 outside of the gate structure 140. Regardless, conductive source/drain contacts 180 may be formed over the source/drain features to provide electrical connectivity thereto. An interlayer dielectric (ILD) 185 is formed over the isolation structures 130 and around the gate structure 140 and the source/drain contacts 180. The ILD 185 may be referred to as an ILD0 layer. In some embodiments, the ILD 185 may include silicon oxide, silicon nitride, or a low-k dielectric material.

The FinFET devices of FIGS. 1A-1B and the GAA devices of FIG. 1C may be utilized to implement electrical circuitries having various functionalities, such as memory devices (e.g., static random access memory (SRAM) devices), logic circuitries, application specific integrated circuit (ASIC) devices, radio frequency (RF) circuitries, drivers, micro-controllers, central processing units (CPUs), image sensors, etc., as non-limiting examples.

FIGS. 2-20 illustrate diagrammatic fragmentary cross-sectional views of a portion of an IC device 200 (in which the FinFET or GAA devices may be implemented) at various stages of fabrication according to various embodiments of the present disclosure. In some embodiments, the portion of IC device 200 illustrated may include an electronic switch implemented using a phase change material (PCM), as discussed below. Note that FIGS. 2-20 illustrate the cross-sectional views along an X-Z plane defined by the X-direction horizontally and the Z-direction vertically.

As shown in FIG. 2, the IC device 200 includes a material layer 210. In some embodiments, the material layer 210 includes silicon carbide (SiC). The IC device 200 also includes an insulating material 220 that is formed over the material layer 210. In some embodiments, the insulating material includes silicon oxide (SiO₂). The IC device 200 further includes a conductive component 250, a conductive component 251, and a heater component 270, which are all embedded in the insulating material 220. The conductive components 250 and 251 are separated from one another in the X-direction by the heater component 270, and also by portions of the insulating material 220.

The conductive components 250 and 251 serve as electrical terminals (or electrodes) for the transmission of an electrical signal, for example, a radio frequency (RF) signal. In other words, the conductive components 250 and 251 may each be connected to RF circuitry (which may be implemented using the FinFET and/or GAA devices discussed above with reference to FIGS. 1A-1C) that are capable of generating electrical signals such as the RF signal. For reasons of simplicity, such RF circuitry is not illustrated in FIG. 2, as the details of the RF circuitry are not the main focus of the scope of the present disclosure. In any case, to facilitate the transmission of the electrical signals, the conductive components 250 and 251 are implemented using a low resistance material. In some embodiments, the conductive components 250 and 251 are implemented using tungsten (W).

The heater component 270 is configured to generate heat. Therefore, the heater component 270 is implemented using a material that can tolerate a high temperature. In some embodiments, the heater component is also implemented using tungsten. It is understood that the portion of the heater component 270 shown in FIG. 2 may correspond to a middle segment of the heater component 270, which may be connected to two opposite end segments of the heater component 270. The two opposite end segments of the heater component 270 are not visible in FIG. 2, but they will be illustrated in the top view figure FIG. 21 that is discussed below in more detail. Electrical voltages may be applied to the heater component 270 via the two end segments to produce thermal energy in the form of heat. As will be discussed below in more detail, the heat produced by the heater component 270 may change a phase of a PCM structure that is to be formed over the heater component 270 in a subsequent fabrication process. As the PCM structure undergoes a phase change, its resistivity may also change, which allows it to function as either a conductor or an insulator, depending on the phase that the PCM structure is in. As such, the PCM structure may function as an electrical switch that can be selectively opened or closed to regulate the transmission of electrical signals therethrough.

The conductive components 250-251 and the heater component 270 may be formed by etching openings in the insulating material 220, and subsequently depositing the suitable conductive materials (e.g., tungsten) to fill these openings. It is understood that a planarization process, such as a chemical mechanical polishing (CMP) process may be performed following the deposition of the conductive materials to planarize the upper surfaces of the conductive components 250-251 and the heater component 270. At this stage of fabrication, the conductive components 250-251 and the heater component 270 may have substantially flat and co-planar upper surfaces.

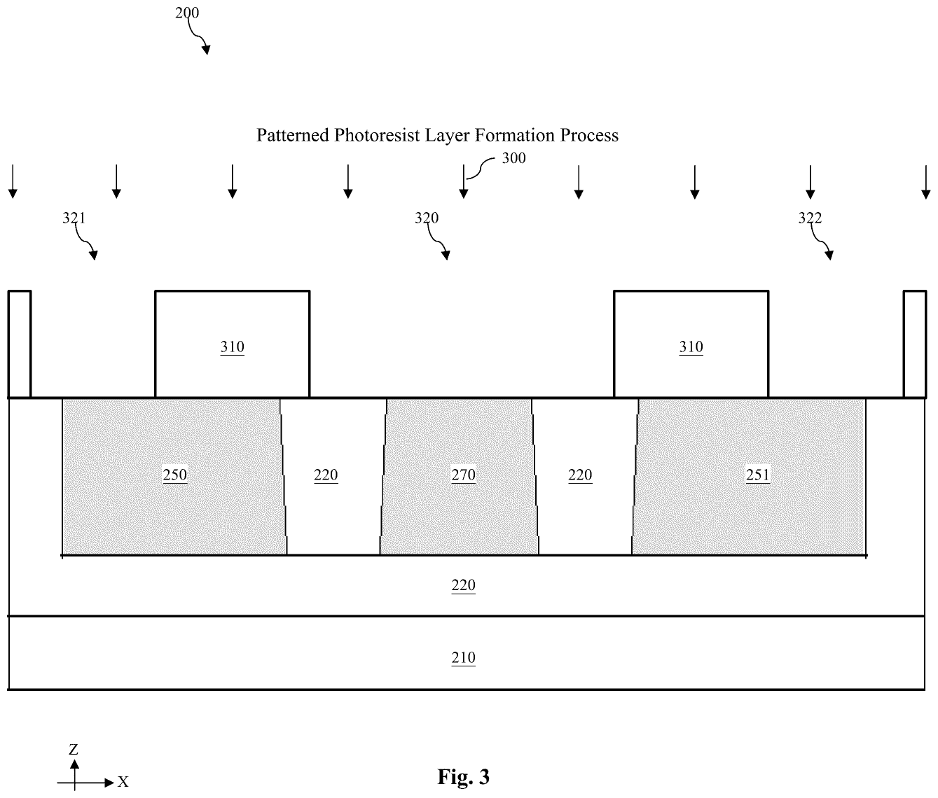

Referring now to FIG. 3, a patterned photoresist layer formation process 300 is performed to the IC device 200. For example, a photoresist material may be spin-coated over the IC device 200. The photoresist material may undergo an exposure process, followed by a post exposure baking process and a developing process to remove portions of the photoresist material. The remaining portions of the photoresist material may form a patterned photoresist layer 310. The patterned photoresist layer 310 may define a plurality of openings, such as openings 320, 321, and 322. As is shown in FIG. 3, the opening 320 exposes the upper surfaces of the heater component 270 and portions of the insulating material 220 surrounding the heater component 270. The opening 321 exposes a portion of the conductive component 250 and a portion of the insulating material 220 adjacent to the conductive component 250. The opening 322 exposes a portion of the conductive component 251 and a portion of the insulating material 220 adjacent to the conductive component 251.

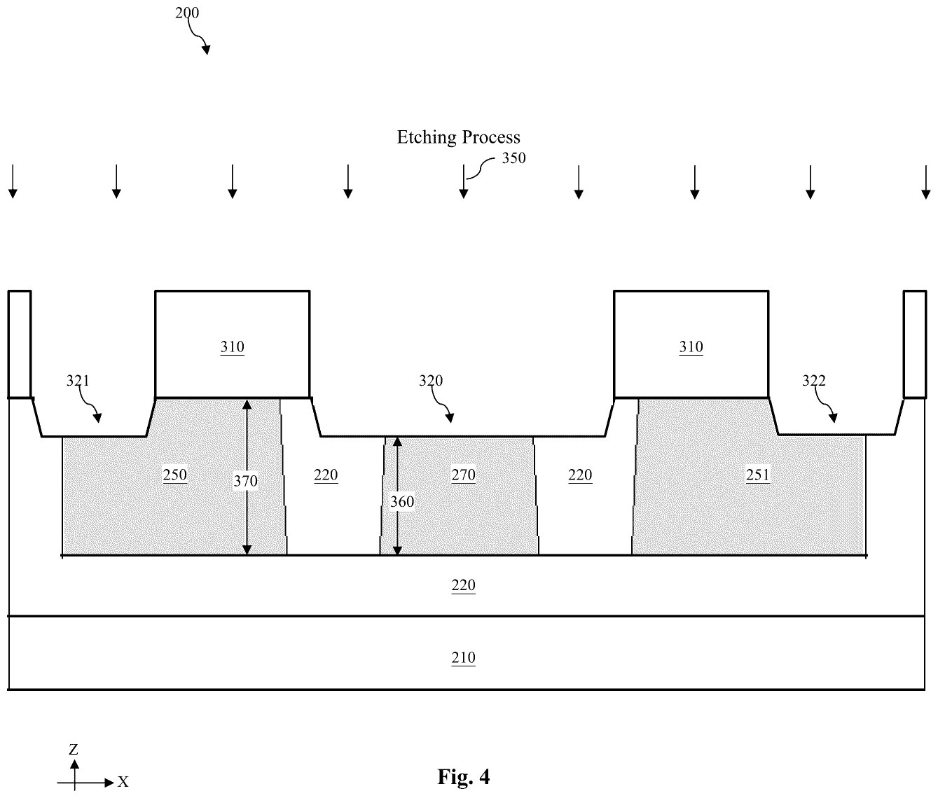

Referring now to FIG. 4, an etching process 350 is performed to the IC device 200 to extend the openings 320-322 further downwards vertically. for example, the etching process 350 may include one or more wet etching processes or dry etching processes to remove portions of the heater component 270, the conductive components 250-251, as well as the insulating material 220 that are exposed by the openings 320-322, while portions of the IC device 200 located under the patterned photoresist layer 310 are protected. In this manner, the patterned photoresist layer 310 serves as an etching mask. In some embodiments, the etching process 350 uses an etchant gas that comprises SF₆, CF₄, CH₂F₂, or O₂.

As a result of the etching process 350, a height 360 of the heater component 270 is less than a maximum height 370 of the conductive component 250 or conductive component 251. In some embodiments, a ratio between the height 360 and the height 370 is in a range between about 1:1.5 and about 1:2.5. It is understood that the above range is not randomly chosen but specifically configured to optimize the performance of the IC device 200. For example, at least the opening 320 will be filled by a dielectric layer in a subsequent process, so that such a dielectric layer may provide electrical isolation between the heater component 270 and the PCM structure that is to be formed over the dielectric layer. If the ratio between the height 360 and the height 370 is too high, that may indicate that the opening 320 has not been extended deep enough, which may result in the dielectric layer 410 filling the opening 320 not being thick enough to provide a sufficient amount of electrical isolation between the heater component 270 and the PCM structure.

On the other hand, if the ratio between the height 360 and the height 370 is too low, that may indicate the opening 320 has been extended unnecessarily deep, which may mean that an excessive amount of the heater component 270 has been removed. When this occurs, the heater component 270 may not be able to generate a sufficient amount of heat to alter the phase of the PCM structure. In addition, the resulting dielectric layer filling the opening 320 may be too thick, in the sense that a substantial amount of the heat generated by the heater component 270 may not be able to reach the PCM above. As such, it may be more difficult to control the temperature of the PCM via the heat generated by the heater component 270.

Here, the above ratio range is optimized to ensure that the subsequently-formed dielectric layer is thick enough to adequately serve as an electrical isolation structure, while also thin enough to not disrupt the intended heat generation functionality of the heater component 270.

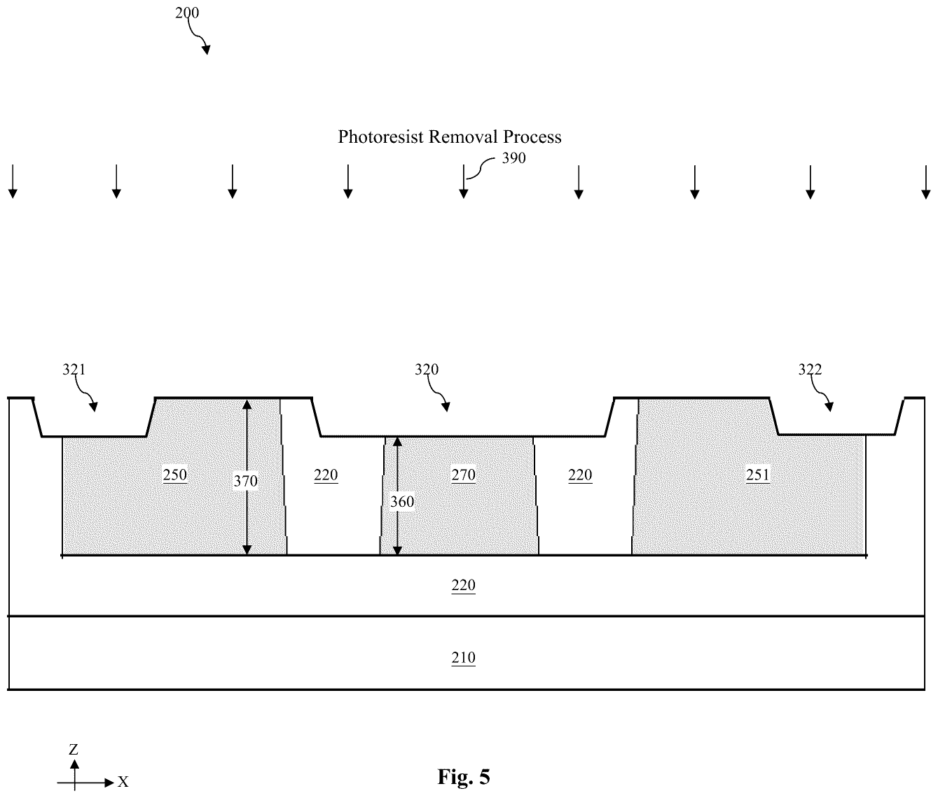

Referring now to FIG. 5, a photoresist removal process 390 is performed to the IC device 200 to remove the patterned photoresist layer 310. In some embodiments, the photoresist removal process 390 includes a photoresist stripping process or a photoresist ashing process. The openings 320-322 that are etched into the insulating material 220, the conductive components 250-251, and the heater component 270 still remain after the patterned photoresist layer 310 is removed.

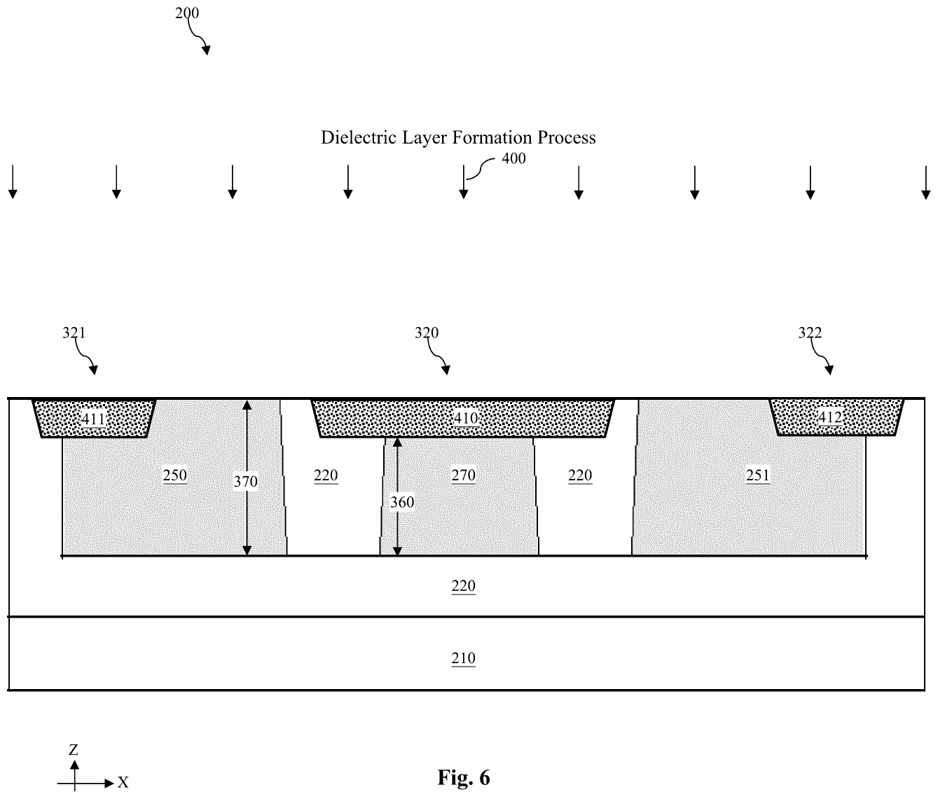

Referring now to FIG. 6, a dielectric layer formation process 400 is performed to the IC device 200. In some embodiments, the dielectric layer formation process 400 includes a deposition process, such as a PVD process, a CVD process, an ALD process, or combinations thereof. The deposition process deposits a dielectric material into the openings 320-322. In some embodiments, the deposition process deposits silicon nitride (SiN) as the dielectric material deposited into the openings 320-322. The dielectric layer formation process 400 may also include a planarization process, such as a CMP process, to remove excess portions of the dielectric material deposited outside of the openings 320-322 and to planarize the upper surface of the deposited dielectric material with the upper surfaces of the insulating material 220 and the conductive components 250-251. As a result of the dielectric layer formation process 400, dielectric layers 410, 411, and 412 are formed in the openings 320, 321, and 322, respectively.

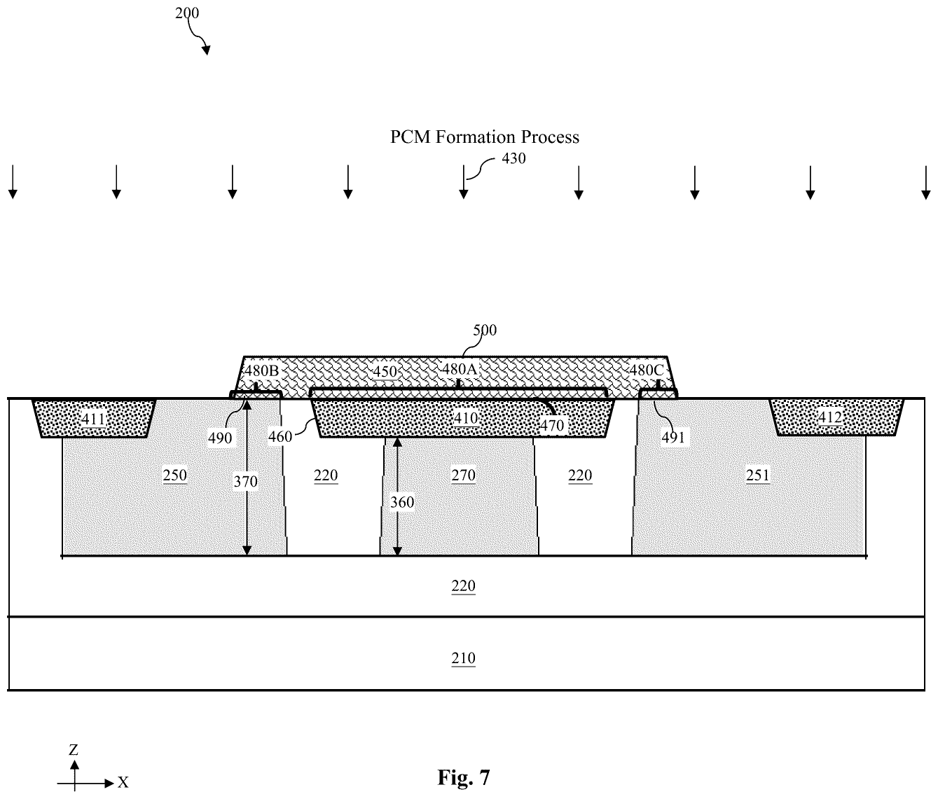

Referring now to FIG. 7, a PCM formation process 430 is performed to the IC device 200 to form a phase change material (PCM) 450. In some embodiments, the PCM formation process 430 includes a deposition process, such as a PVD process, a CVD process, an ALD process, or combinations thereof. As shown in FIG. 7, the PCM 450 is formed over the upper surfaces of the dielectric layer 410, portions of the insulating material 220 surrounding the dielectric layer 410, as well as portions of the conductive components 250 and 251. Note that as an inherent result of the unique fabrication process flow being performed herein, a side surface 460 of the dielectric layer 410 is in direct physical contact with the insulating material 220, but not with the PCM 450. Rather, an upper surface 470 of the dielectric layer 410 is in direct physical contact with a portion 480A of a bottom surface of the PCM 450. Another portion 480B of the bottom surface of the PCM 450 is in direct contact with an upper surface 490 of the conductive component 250, and yet another portion 480C of the bottom surface of the PCM 450 is in direct contact with an upper surface 491 of the conductive component 251. This is because the upper surfaces 470 and 490-491 have been planarized prior to the formation of the PCM 450, which results in the flat bottom surface of the PCM 450 (but not other parts of the PCM 450) that is in direct contact with the conductive components 250-251 and the heater component 270.

In some embodiments, the PCM formation process 430 deposits a germanium telluride (GeTe) material as the PCM. The GeTe material can change its phase from an amorphous phase to a crystal phase, or vice versa, based on a temperature of the GeTe material. The temperature of the GeTe material (i.e., a temperature of the PCM 450) can change in response to the heat generated by the heater component 270. In that regard, although the PCM 450 is electrically insulated from the heater component 270 by the dielectric layer 410, the heat produced by the heater component can and will affect the PCM 450. For example, as an electrical voltage is applied to the heater component 270 to cause the heater component 270 to generate heat, the temperature at the PCM 450 may begin to rise. When such a temperature reaches a crystallization temperature of the PCM 450 (e.g., at about 200 degrees Celsius), the PCM 450 will change into a crystal phase, which is highly conductive (e.g., has a low resistivity). In other words, when the heat generated by the heater component 270 causes the PCM 450 to switch into the crystal phase, the high conductivity and/or low resistivity causes the PCM 450 to effectively function as a closed electrical switch. In this state, electrical signals (e.g., RF signals) may be transmitted between the conductive components 250-251 through the PCM 450.

If it is desired for the PCM 450 to continue to function as a closed electrical switch, then the heater component 270 may be configured to not generate additional heat. For example, no electrical voltage may be applied to the heater component 270, which may cause the heater component 270 to cease the heat generation (at least temporarily). As a result, the temperature at the PCM 450 may no longer rise, and in fact may drop back down to room temperature (e.g., around 25 degrees Celsius). Since the PCM 450 is already in the crystal state, it may remain in the crystal state under the room temperature and therefore continue to serve as a closed electrical switch.

However, if it is desired for the PCM 450 to begin to function as an open electrical switch, then the heater component 270 may be configured to generate even more heat, such that the temperature at the PCM 450 reaches a melting point (e.g., at 500 degrees Celsius or higher). Thereafter, the PCM 450 may be cooled rapidly. This process will return the PCM 450 to an amorphous state, which is associated with a low conductivity and/or high resistivity. Such a low conductivity and/or high resistivity effectively turns the PCM 450 into an electrically insulating material, which allows it to serve as an open electrical switch. Therefore, the PCM 450 may prevent the transmission of electrical signals between the conductive components 250-251 when the PCM 450 is operating under the electrical open state.

As discussed above, since the prior fabrication processes (e.g., CMP) have already planarized the upper surface 470 of the dielectric layer 410 with the upper surfaces 490-491 of the conductive components 250-251, the PCM 450 herein is formed as a substantially flat structure. For example, a bottom surface of the PCM 450 is substantially flat (e.g., flat in its entirety). This is manifested at least in part by the fact that the portion 480A of the bottom surface of the PCM 450 is substantially co-planar with the portion 480B of the bottom surface of the PCM 450. In addition, the PCM 450 also has a substantially flat top surface 500 (e.g., an entirety of the top surface 500 is flat). According to various aspects of the present disclosure, the substantially flat top and bottom surfaces of the PCM 450 are unique physical characteristics of the IC device 200. Such a flat cross-sectional profile of the PCM eliminates (or at least substantially reduces) the step height issue that plagues conventional PCM devices. Advantageously, the flat profile (and lack of step height) reduces the clustering of germanium atoms, which will lead to an improved device performance and a longer lifetime.

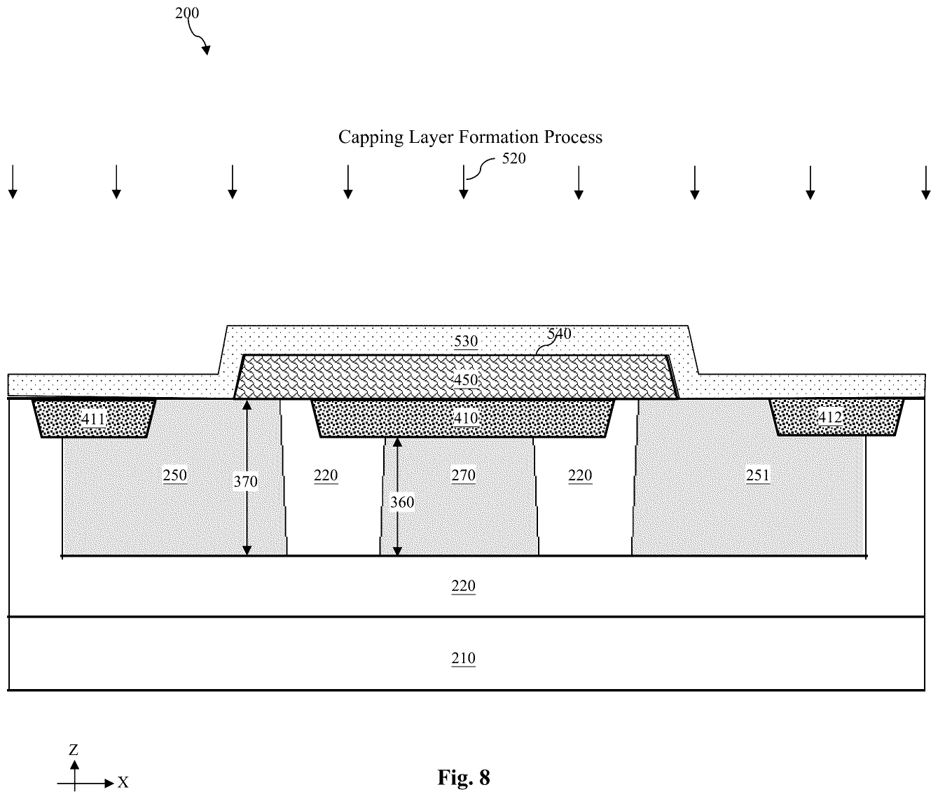

Referring now to FIG. 8, a capping layer formation process 520 is performed to the IC device 200 to form a capping layer 530. In some embodiments, the capping layer formation process 520 includes a deposition process, such as a PVD process, a CVD process, an ALD process, or combinations thereof. The deposition process deposits a dielectric material, such as silicon nitride, as the capping layer 530 over the upper surfaces of the PCM 450, the dielectric layers 411-412, and the conductive components 250-251. A bottom surface of a portion of the capping layer 530 is in direct physical contact with the upper surface of the PCM 450 and forms an interface 540 with the upper surface of the PCM 450. Since the upper surface of the PCM 450 is substantially flat, this interface 540 between the capping layer 530 and the PCM 450 is also substantially flat. The capping layer 530 may protect the PCM 450 from various elements. For example, since the capping layer 530 seals the PCM 450 underneath, the PCM 450 will not be exposed to oxygen, and as such, will not become oxidized. Since oxidation would have adversely affected the performance of the PCM 450 as an electronic switch, the capping layer 530 helps to protect the PCM 450 from undesirable oxidation, and therefore, improves device performance.

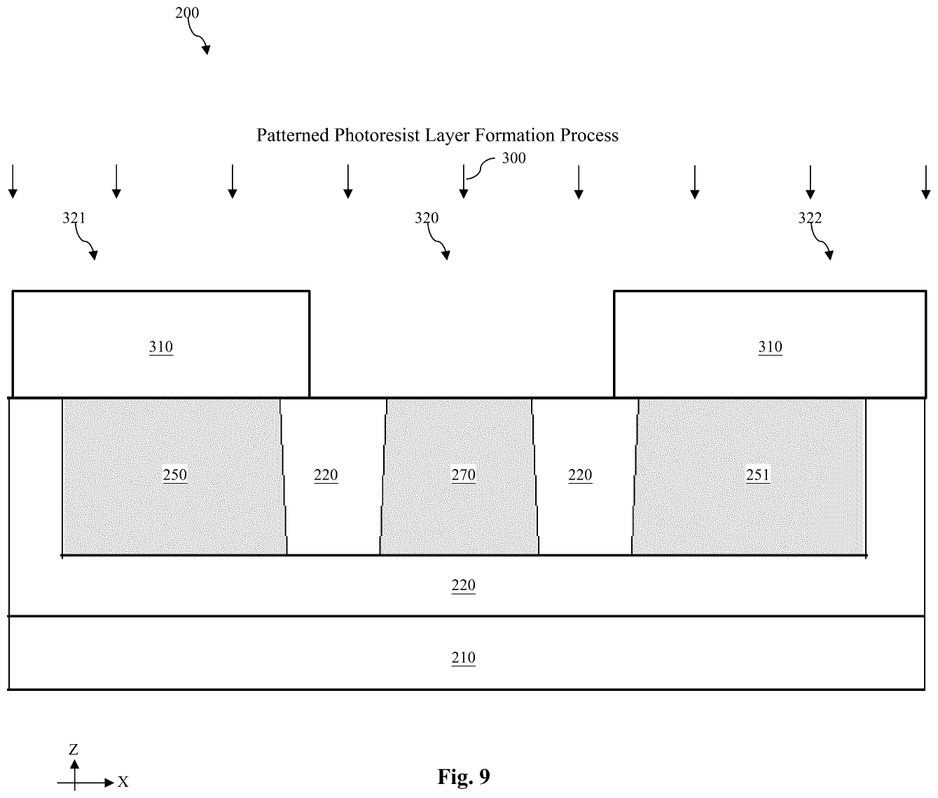

It is understood that FIGS. 2-8 illustrate the cross-sectional side views corresponding to a first embodiment of the fabrication process flow of the present disclosure. FIGS. 9-14 illustrate the cross-sectional side views corresponding to a second embodiment of the fabrication process flow of the present disclosure. For reasons of consistency and clarity, similar components and/or processes in the first embodiment and the second embodiment are labeled the same.

Referring now to FIG. 9, the IC device 200 is provided that includes the material layer 210, the insulating material 220, the conductive components 250-251, and the heater component 270. The patterned photoresist layer formation process 300 is also performed to the IC device 200 to form a patterned photoresist layer 310. However, unlike the patterned photoresist layer 310 in FIG. 3, the patterned photoresist layer 310 in FIG. 9 does not define the openings 321-322. Instead, the patterned photoresist layer 310 defines just the opening 320 that exposes the upper surfaces of the heater component 270 and portions of the insulating material 220 surrounding the heater component 270, while the conductive components 250-251 are covered up by the patterned photoresist layer 310.

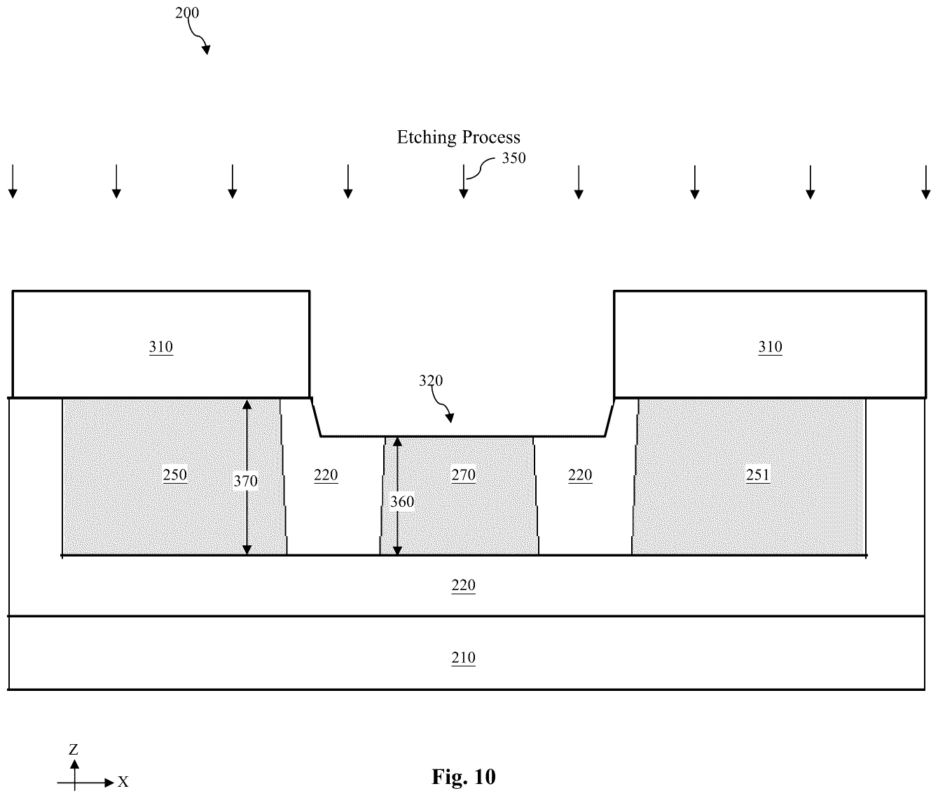

Referring now to FIG. 10, the etching process 350 is performed to the IC device 200 to extend the opening 320 further downwards. For example, the etching process 350 may include one or more wet etching processes or dry etching processes to remove portions of the heater component 270 and the insulating material 220 that are exposed by the opening 320, while portions of the IC device 200 located under the patterned photoresist layer 310 are protected. In this manner, the patterned photoresist layer 310 serves as an etching mask. As was the case in the first embodiment, the etching process 350 results in a lower height 360 of the heater component 270 than the height 370 of the conductive components 250-251.

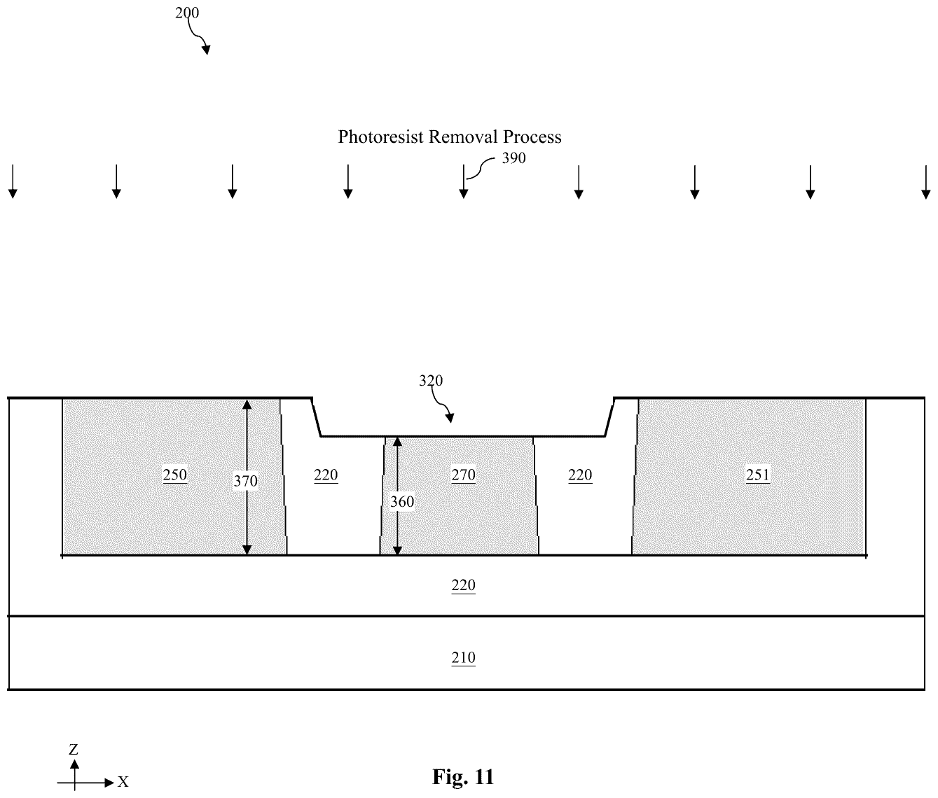

Referring now to FIG. 11, the photoresist removal process 390 is performed to the IC device 200 to remove the patterned photoresist layer 310. In some embodiments, the photoresist removal process 390 includes a photoresist stripping process or a photoresist ashing process. The opening 320 that is etched into the insulating material 220 and the heater component 270 still remains after the patterned photoresist layer 310 is removed.

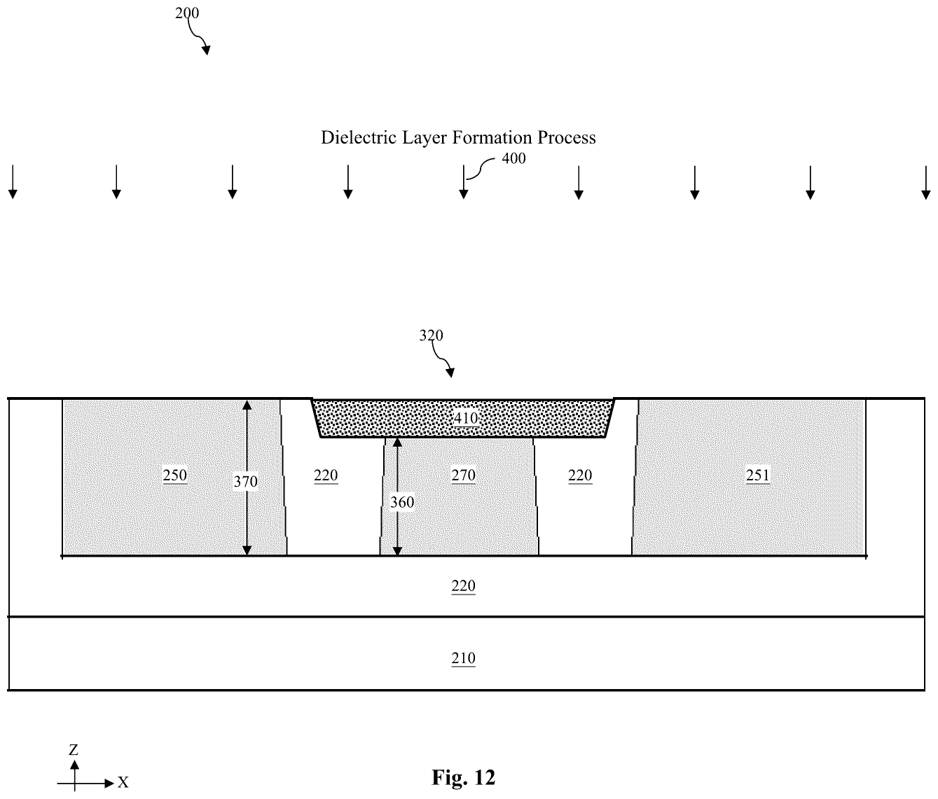

Referring now to FIG. 12, the dielectric layer formation process 400 is performed to the IC device 200 to deposit a dielectric material (e.g., SiN) into the opening 320. A planarization process, such as a CMP process, may also be performed to remove excess portions of the dielectric material deposited outside of the opening 320 and to planarize the upper surface of the deposited dielectric material with the upper surfaces of the insulating material 220 and the conductive components 250-251. As a result of the dielectric layer formation process 400, the dielectric layer 410 is formed in the opening 320.

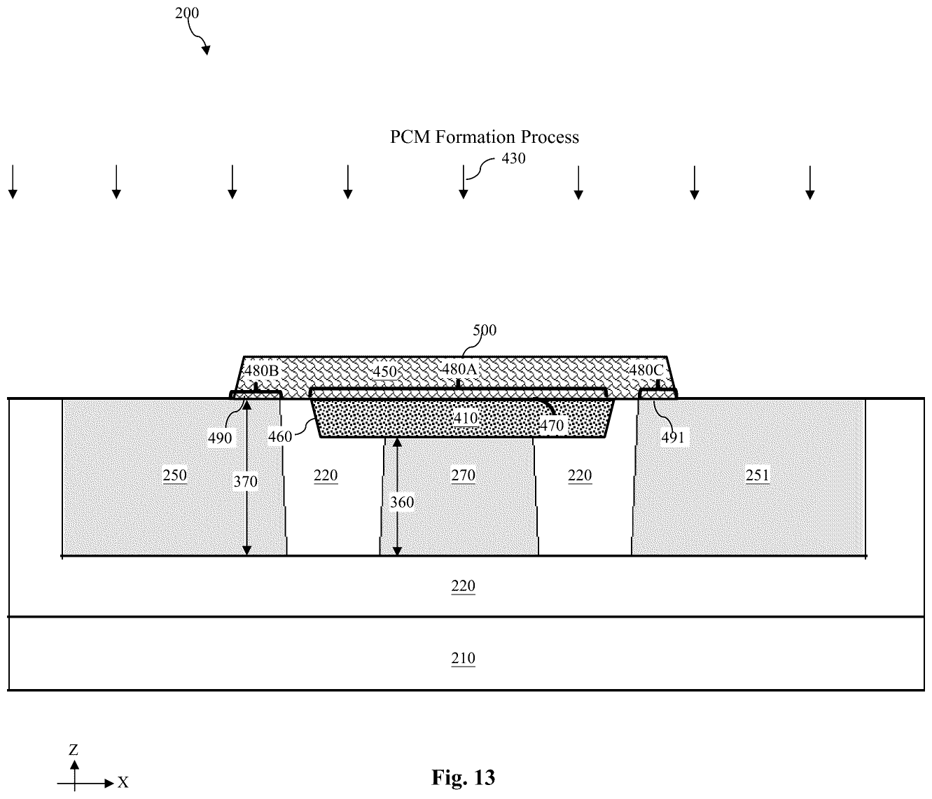

Referring now to FIG. 13, the PCM formation process 430 is performed to the IC device 200 to form the PCM 450. The PCM 450 is formed over the upper surfaces of the dielectric layer 410, portions of the insulating material 220 surrounding the dielectric layer 410, as well as portions of the conductive components 250 and 251. The operation of the PCM 450 (e.g., by changing its phase in response to the heat generated by the heater component 270) is substantially similar to that discussed above in the first embodiment.

Similar to the first embodiment, the PCM 450 in the second embodiment (shown in FIG. 13 herein) also has a flat upper surface 500 and a flat bottom surface. For example, the portion 480A of the bottom surface of the PCM 450 is in direct physical contact with the upper surface 470 of the dielectric layer 410, and the portions 480B-480C of the bottom surface of the PCM 450 are in direct contact with the upper surfaces 490-491 of the conductive components 250-251, respectively. Such a flat cross-sectional profile of the PCM 450 eliminates (or at least substantially reduces) the step height issue that plagues conventional PCM devices, and consequently will lead to an improved device performance and a longer lifetime (e.g., since the reduction in the step height also reduces the clustering of germanium atoms). Note that another inherent result of the flat profile of the PCM 450 is that the side surface 460 of the dielectric layer 410 is in direct physical contact with the insulating material 220, rather than being in direct physical contact with the PCM 450.

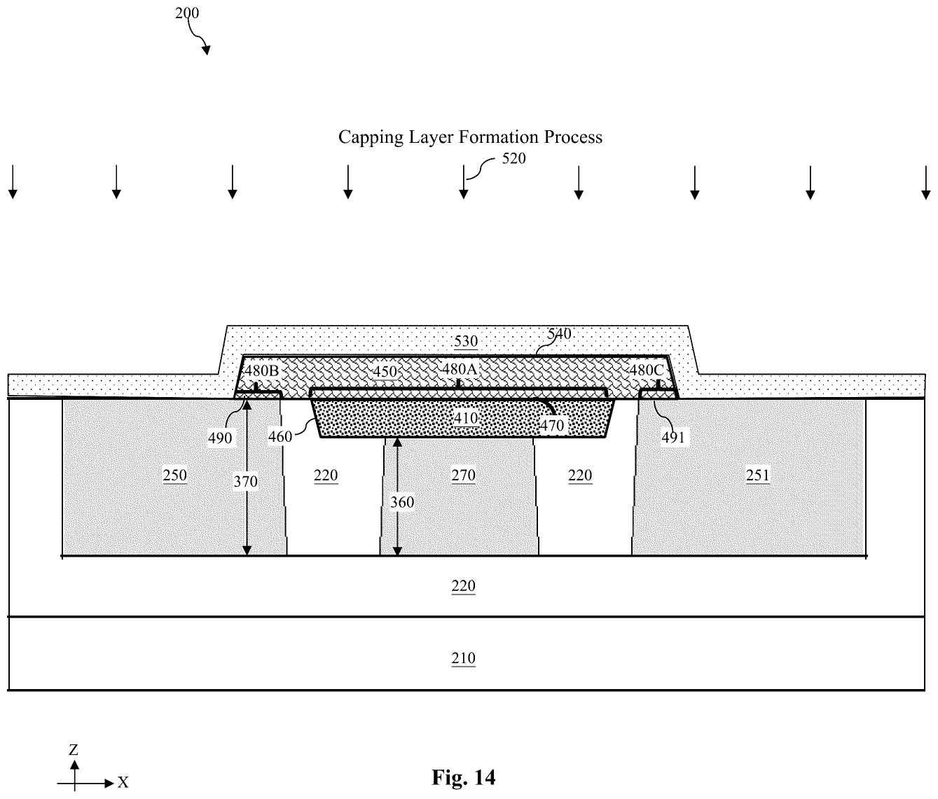

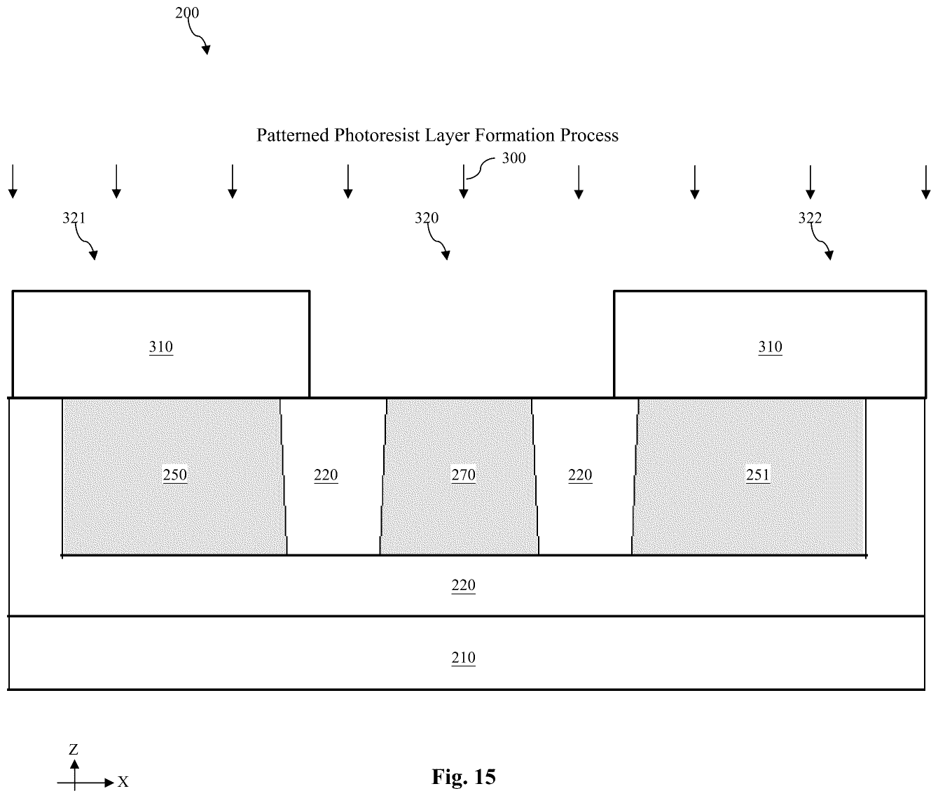

Referring now to FIG. 14, the capping layer formation process 520 is performed to the IC device 200 to form the capping layer 530 over the upper surfaces of the PCM 450 and the conductive components 250-251. As is the case in the first embodiment, the bottom surface of the capping layer 530 in the second embodiment also forms a flat interface 540 with the upper surface of the PCM 450. As discussed above, the capping layer 530 helps to protect the PCM 450 from elements such as undesirable oxidation.

FIGS. 15-20 illustrate the cross-sectional side views corresponding to a third embodiment of the fabrication process flow of the present disclosure. For reasons of consistency and clarity, similar components and/or processes in the first embodiment, the second embodiment, and the third embodiment are labeled the same.

Referring now to FIG. 15, the IC device 200 is provided that includes the material layer 210, the insulating material 220, the conductive components 250-251, and the heater component 270. The patterned photoresist layer formation process 300 is also performed to the IC device 200 to form a patterned photoresist layer 310. As is the case for the second embodiment, the patterned photoresist layer 310 in the third embodiment is formed to define just the opening 320 that exposes the upper surfaces of the heater component 270 and portions of the insulating material 220 surrounding the heater component 270, while the conductive components 250-251 are covered up by the patterned photoresist layer 310.

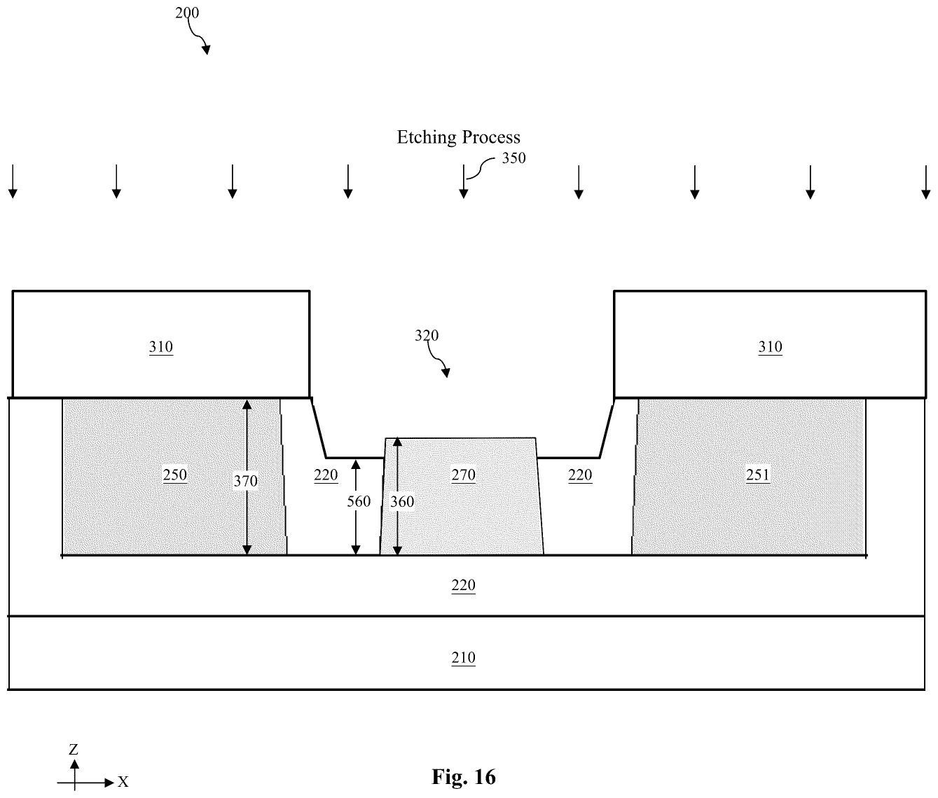

Referring now to FIG. 16, the etching process 350 is performed to the IC device 200 to extend the opening 320 further downwards. Similar to the second embodiment, the etching process 350 herein remove portions of the heater component 270 and the insulating material 220 that are exposed by the opening 320, while portions of the IC device 200 located under the patterned photoresist layer 310 are protected. However, compared to the etching process 350 of the first or the second embodiments discussed above, the etching process 350 in the third embodiment shown in FIG. 16 is configured with a greater etching selectivity between the insulating material 220 and the heater component 270. For example, the etching process 350 may be configured to etch away the insulating material 220 at a greater rate than the heater component 270. As a result, a height 560 of the portion of the insulating material 220 exposed by the opening 320 is less than the height 360 of the heater component 270, which itself is less than the height 370 of the conductive components 250-251. Alternatively stated, the upper surface of the heater component 270 is more elevated vertically than an upper surface of the remaining portion of the insulating material 220 exposed by the opening 320.

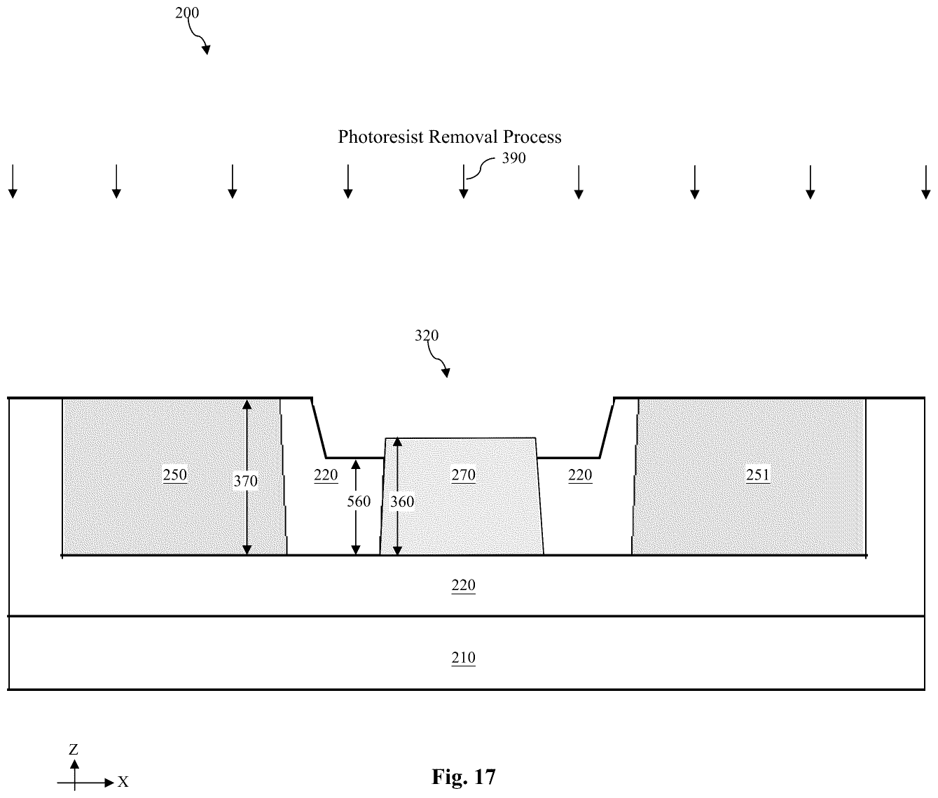

Referring now to FIG. 17, the photoresist removal process 390 is performed to the IC device 200 to remove the patterned photoresist layer 310. In some embodiments, the photoresist removal process 390 includes a photoresist stripping process or a photoresist ashing process. The opening 320 that is etched into the insulating material 220 and the heater component 270 still remains after the patterned photoresist layer 310 is removed.

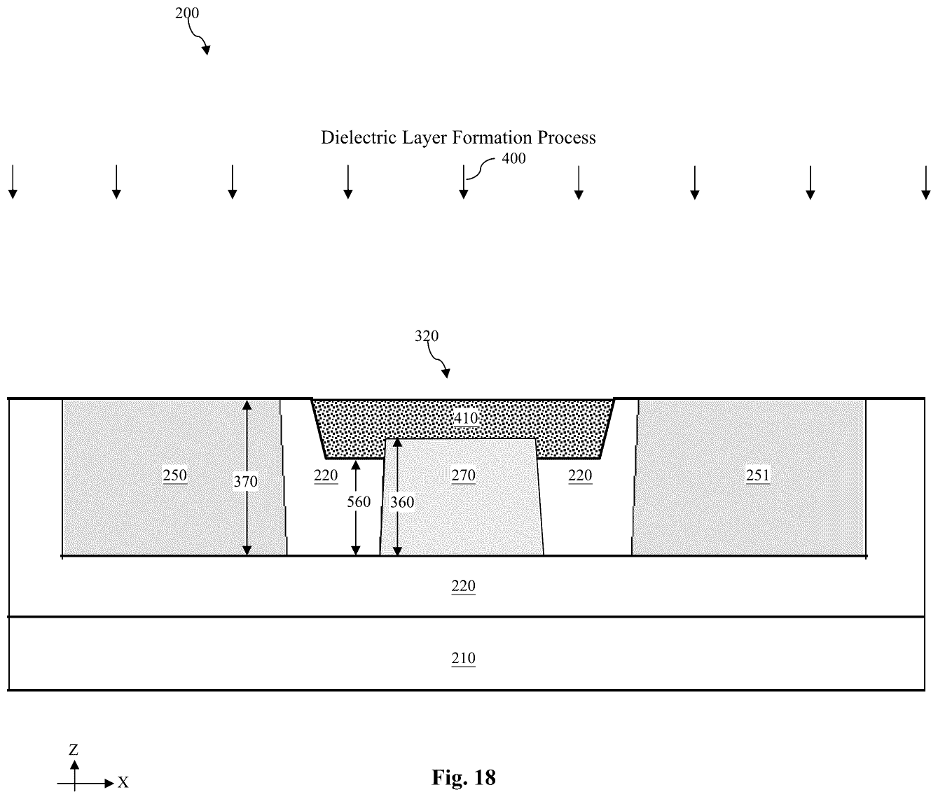

Referring now to FIG. 18, the dielectric layer formation process 400 is performed to the IC device 200 to deposit a dielectric material (e.g., SiN) into the opening 320. A planarization process, such as a CMP process, may also be performed to remove excess portions of the dielectric material deposited outside of the opening 320 and to planarize the upper surface of the deposited dielectric material with the upper surfaces of the insulating material 220 and the conductive components 250-251. As a result of the dielectric layer formation process 400, the dielectric layer 410 is formed in the opening 320. Note that due to the greater height 360 of the heater component 270 (e.g., compared to the height 560 of the insulating material 220), the heater component 270 protrudes vertically into the dielectric layer 410.

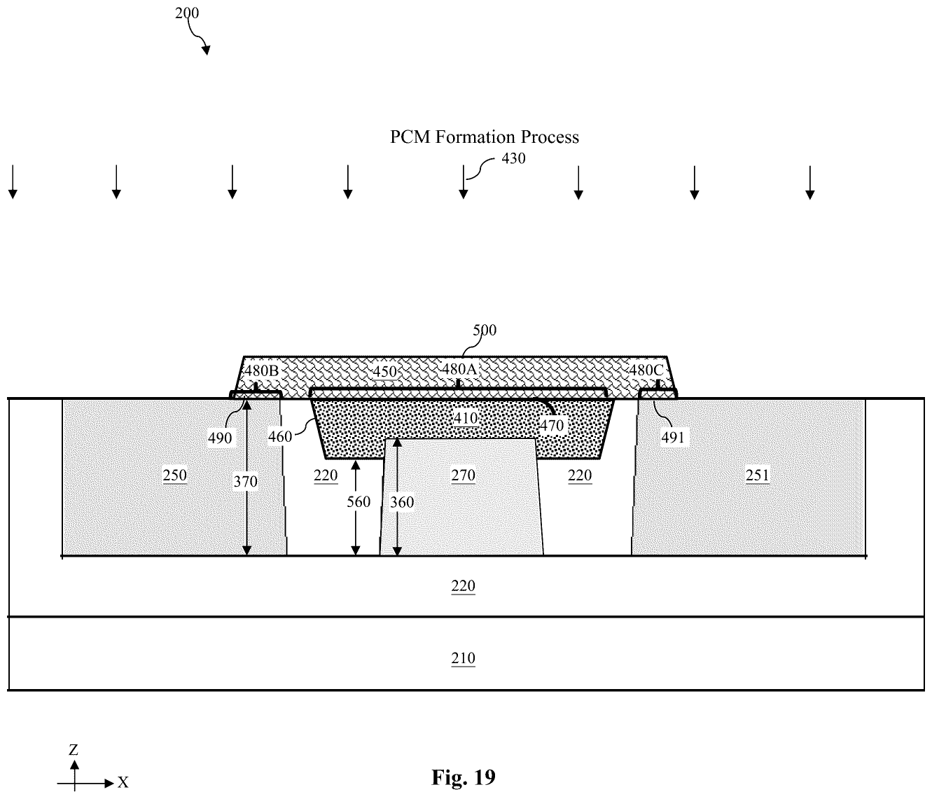

Referring now to FIG. 19, the PCM formation process 430 is performed to the IC device 200 to form the PCM 450. The PCM 450 is formed over the upper surfaces of the dielectric layer 410, portions of the insulating material 220 surrounding the dielectric layer 410, as well as portions of the conductive components 250 and 251. The operation of the PCM 450 (e.g., by changing its phase in response to the heat generated by the heater component 270) is substantially similar to that discussed above in the first and second embodiments.

Similar to the first and second embodiments, the PCM 450 in the third embodiment (shown in FIG. 19 herein) also has a flat upper surface 500 and a flat bottom surface. For example, the portion 480A of the bottom surface of the PCM 450 is in direct physical contact with the upper surface 470 of the dielectric layer 410, and the portions 480B-480C of the bottom surface of the PCM 450 are in direct contact with the upper surfaces 490-491 of the conductive components 250-251, respectively. Such a flat cross-sectional profile eliminates (or at least substantially reduces) the step height issue that plagues conventional PCM devices, and consequently will lead to an improved device performance and a longer lifetime (e.g., since the reduction in the step height also reduces the clustering of germanium atoms). Note that another inherent result of the flat profile of the PCM 450 is that the side surface 460 of the dielectric layer 410 is in direct physical contact with the insulating material 220, rather than being in direct physical contact with the PCM 450.

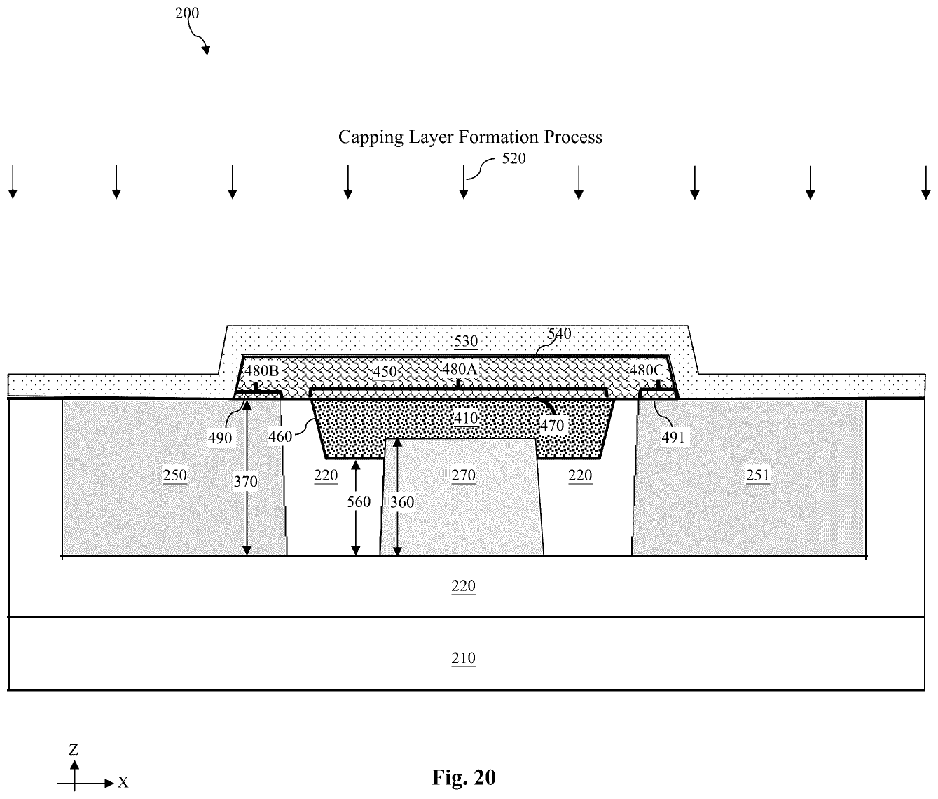

Referring now to FIG. 20, the capping layer formation process 520 is performed to the IC device 200 to form the capping layer 530 over the upper surfaces of the PCM 450 and the conductive components 250-251. As is the case in the first embodiment, the bottom surface of the capping layer 530 in the second embodiment also forms a flat interface 540 with the upper surface of the PCM 450. As discussed above, the capping layer 530 helps to protect the PCM 450 from elements such as undesirable oxidation.

To provide further clarity to the various aspect of the present disclosure, FIG. 21 illustrates a planar top view of a portion of the IC device 200. The Top view of FIG. 21 is defined by an X-direction and a Y-direction that is perpendicular to the X-direction. In FIG. 21, the X-direction extends horizontally, and the Y-direction extends vertically. A cutline A-A′ spans across the conductive components 250-251 and a middle segment of the heater component 270, where the cross-sectional side views of FIGS. 2-20 discussed above are taken along the cutline A-A′.

As shown in the top view of FIG. 21, the conductive components 250 and 251 are spaced apart and separated from each other. A middle segment of the heater component 270 is located between the conductive components 250 and 251. The middle segment of the heater component 270 extends in an elongated manner in the Y-direction. The heater component 270 also includes two end segments 270A and 270B at opposite ends of the middle segment of the heater component 270. The two end segments 270A and 270B may serve as electrode terminals for receiving electrical voltages that are applied to the heater component 270 to produce heat. The heat generated by the heater component 270 will in turn change the temperature of the PCM 450 (whose boundary is illustrated in FIG. 21 as dashed outlines), since the PCM 450 overlaps with the middle segment of the heater component 270 in the top view.

As discussed above, the PCM 450 will switch between a crystal phase and an amorphous phase depending on its temperature, which allows its conductivity/resistivity to change. Since the PCM 450 is electrically coupled to both of the conductive components 250 and 251, it may serve as an electrical switch to control the transmission of electrical signals between the conductive components 250 and 251. As discussed above, the PCM 450 has a substantially flat profile, which reduces the clustering of germanium atoms, and as a result, improves the performance and/or lifetime of the PCM 450 as a part of an electrical switch. However, such a flat profile is not directly visible in the top view of FIG. 21, though it is evident in the cross-sectional side views of FIGS. 7-8, 13-14, and 19-20.

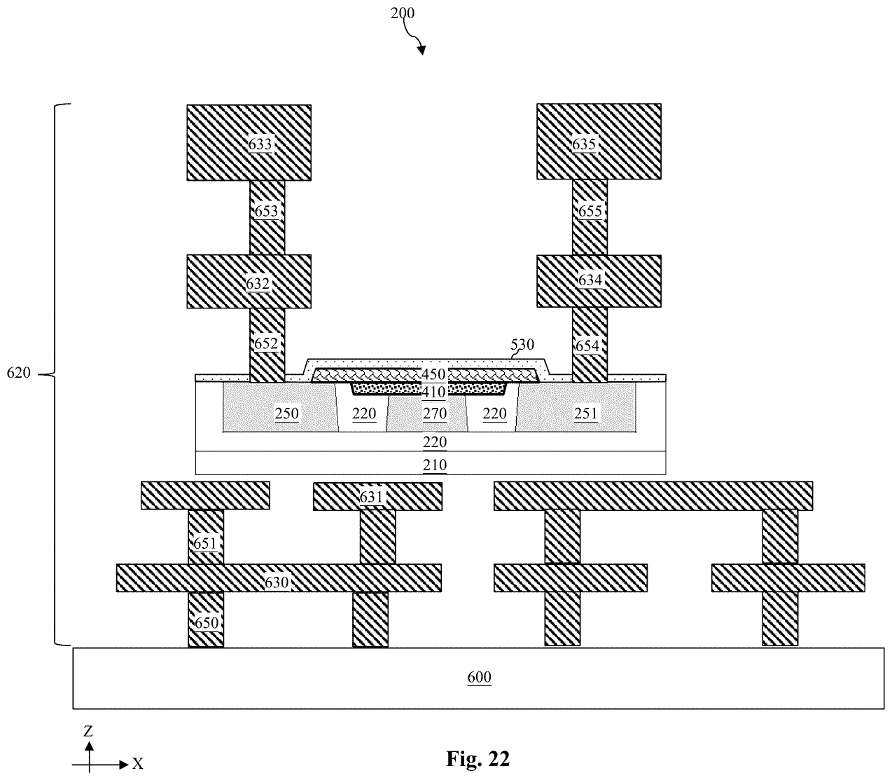

To provide even more clarity to the various aspect of the present disclosure, FIG. 22 illustrates a cross-sectional side view (e.g., in a plane defined by the X-direction and the Z-direction) of a greater portion of the IC device 200, which shows how the PCM switch discussed above may be implemented within the IC device 200 according to an example embodiment.

As shown in FIG. 22, the IC device 200 includes electrical circuitry 600. In some embodiments, the electrical circuitry 600 may include front-end circuitry for an RF IC application. For example, the electrical circuitry 600 may contain logic circuitry, which may include gates such as NAND gates, NOR gates, XOR gates, inverters, etc. These gates and/or other circuit building blocks may be used to implement circuits such as oscillators, filters, amplifiers, mixers, multiplexers, etc. It is understood that the components of the electrical circuitry 600 may be implemented using the FinFET devices and/or the GAA devices discussed above with reference to FIGS. 1A-1C. For reasons of simplicity, the details of the electrical circuitry 600 are not specifically illustrated herein.

The IC device 200 shown in FIG. 22 also includes a multi-layer interconnect structure 620, which may be formed over, and provides electrical connectivity to, the electrical circuitry 600. The multi-layer interconnect structure 620 may include a plurality of metal layers (e.g., M0, M1, M2, etc.) that contain interconnection elements such as metal lines, as well as conductive vias that vertically interconnect different metal lines from different metal layers. As non-limiting examples, some of the metal lines 630, 631, 632, 633, 634, and 635, as well as some of the conductive vias 650, 651, 652, 653, 654, and 655, are labeled in FIG. 22. It is understood that for reasons of simplicity, FIG. 22 may not illustrate all of the metal layers of the interconnect structure 620.

The PCM-based electrical switch discussed above with reference to FIGS. 2-21 above may be embedded in one of the metal layers of the interconnect structure 620. Metal layers may be implemented both above and/or below the PCM-based electrical switch to provide electrical connectivity to the switch. In the example shown in FIG. 22, the conductive component 250 is electrically coupled to the conductive via 652, and the conductive component 251 is electrically coupled to the conductive via 654. The conductive via 652 is electrically connected to the metal line 633 through the metal line 632 and the conductive via 653, and the conductive via 654 is electrically connected to the metal line 635 through the metal line 634 and the conductive via 655.

As discussed above, the heater component 270 may generate heat, which causes the PCM 450 to switch between a conductive state and a non-conductive state. When the PCM 450 is in the conductive state, it serves as a closed electrical switch, which allows electrical signals to be transmitted from the metal line 633 to the metal line 635, and vice versa, through the metal lines 632, 634, the vias 652-655, and the conductive components 250-251 below. When the PCM 450 is in the non-conductive state, it serves as an open electrical switch, which prevents the transmission of electrical signals between the metal lines 633 and 635. As discussed above, the flat profile of the PCM 450 herein improves the performance and/or lifetime of the PCM 450 as the electrical switch in this example.

FIG. 23 illustrates an integrated circuit fabrication system 900 that may be used to fabricate the IC device 200 according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such the processing tools to perform the various deposition processes discussed above; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

FIG. 24 is a flowchart illustrating a method 1000 of fabricating a semiconductor device. The method 1000 includes a step 1010 to provide a device that includes a first conductive component, a second conductive component, and a heater component. A segment of the heater component is disposed between the first conductive component and the second conductive component in a cross-sectional side view.

The method 1000 includes a step 1020 to form a patterned photoresist layer over the device. The patterned photoresist layer at least partially covers the first conductive component and the second conductive component. The patterned photoresist layer defines an opening that exposes the segment of the heater component.

The method 1000 includes a step 1030 to perform an etching process to the device while the patterned photoresist layer serves as a protective mask, such that the etching process removes a portion of the segment of the heater component, while portions of the first conductive component and the second conductive component are protected from being etched by the patterned photoresist layer.

The method 1000 includes a step 1040 to form a dielectric layer over the heater component. The dielectric layer, the first conductive component, and the second conductive component have substantially co-planar upper surfaces in the cross-sectional side view.

The method 1000 includes a step 1050 to form a phase change material (PCM) over the substantially co-planar upper surfaces of the dielectric layer, the first conductive component, and the second conductive component, such that a bottom surface of the PCM is substantially flat in the cross-sectional side view.

In some embodiments, the heater component is separated from the first conductive component and the second conductive component by an insulating material. In some embodiments, the etching process partially removes the insulating material at a greater rate than the heater component, such that an upper surface of the heater component is more elevated vertically than the insulating material in the cross-sectional side view after the etching process has been performed.

In some embodiments, the patterned photoresist layer further defines additional openings that partially expose the first conductive component or the second conductive component. In some embodiments, the etching process partially removes the first conductive component or the second conductive component exposed by the additional openings, thereby forming a recess in the first conductive component or the second conductive component.

In some embodiments, the forming the dielectric layer includes filling the recess with a portion of the dielectric layer. The portion of the dielectric layer and a remaining portion of the first conductive component or the second conductive component have substantially co-planar upper surfaces.

In some embodiments, the heater component generates heat in response to an electrical voltage. In some embodiments, a resistivity of the PCM changes in response to heat generated by the heater component. In some embodiments, an electrical path between the first conductive component and the second conductive component is switched on or switched off based on a change in the resistivity of the PCM.

It is understood that additional steps may be performed before, during, or after the steps 1010-1050. For example, in some embodiments, the method 1000 may further include the steps of forming a capping layer over the PCM. In some embodiments, a bottom surface of the capping layer and an upper surface of the PCM form an interface. In some embodiments, an entirety of the interface is substantially flat. For reasons of simplicity, other additional processes are not discussed herein in detail.

Based on the above discussions, it can be seen that the present disclosure implements a unique fabrication process flow to implement a flat PCM structure as a part of an electrical switch in an IC. An etching process may be performed to an IC that includes a heater component between two conductive components. The etching process removes a portion of the heater component to form an opening, which is filled by a dielectric layer subsequently. The upper surfaces of the dielectric layer and the conductive components are planarized via a CMP process. A PCM structure (e.g., containing GeTe) is then formed on these planarized upper surfaces, so that the PCM structure can also achieve a flat profile (e.g., having flat top and bottom surfaces) in a cross-sectional side view. The PCM is configured to switch between a crystal phase (having a low resistivity) and an amorphous phase (having a high resistivity) based on the amount of heat generated by the heater component, thereby functioning as an electrical switch. A capping layer is formed over the PCM structure to protect the PCM structure from oxidation.

The unique fabrication process flow and the resulting IC device structure of the present disclosure offers advantages over conventional devices. It is understood, however, that no particular advantage is required, other embodiments may offer different advantages, and that not all advantages are necessarily disclosed herein. One advantage is the improvement in device performance and lifetime. In that regard, conventional electrical switches are formed to have a step height, which may be a result of the PCM being formed over a non-flat surface. In other words, the PCM in conventional switches may be bent, and the resulting step height may cause a clustering of germanium atoms at or near the step height. This may alter the material composition of the PCM, which may negatively affect its intended operation as an electrical switch and/or may shorten the lifetime of the electrical switch. In comparison, the PCM implemented according to the various aspects of the present disclosure can achieve a substantially flat profile (e.g., in a cross-sectional side view), since the PCM is formed over planarized (e.g., flat) upper surfaces. In other words, the PCM inherits the flat profile of the flat upper surfaces on which the PCM is formed. The flat profile of the PCM substantially eliminates or reduces the step height issue, which in turn eliminates or reduces the occurrence of clustering germanium atoms. Consequently, the device performance and/or the lifetime of the PCM-based electrical switch may be improved. Other advantages may include ease of fabrication and compatibility with existing fabrication processes.

The advanced lithography process, method, and materials described above can be used in many applications, including in IC devices using fin-type field effect transistors (FinFETs). For example, the fins may be patterned to produce a relatively close spacing between features, for which the above disclosure is well suited. In addition, spacers used in forming fins of FinFETs, also referred to as mandrels, can be processed according to the above disclosure. It is also understood that the various aspects of the present disclosure discussed above may apply to multi-channel devices such as Gate-All-Around (GAA) devices. To the extent that the present disclosure refers to a fin structure or FinFET devices, such discussions may apply equally to the GAA devices.

One aspect of the present disclosure pertains to a device. The device includes a material layer. The device includes a first conductive component and a second conductive component each disposed over the material layer in a cross-sectional side view. The device includes a heater component disposed over the material layer in the cross-sectional side view. A segment of the heater component is disposed between the first conductive component and the second conductive component on the cross-sectional side view and in a planar top view. An upper surface of the heater component is less elevated vertically than an upper surface of the first conductive component or the second conductive component in the cross-sectional side view. The device includes a phase change material (PCM) disposed over the segment of the heater component and at least partially over the first conductive component and the second conductive component in the cross-sectional side view. A resistivity of the PCM changes in response to an application of heat. The heat is produced by the heater component.

Another aspect of the present disclosure pertains to a device. The device includes a first conductive component, a second conductive component, and a heater component. A segment of the heater component is located between the first conductive component and the second conductive component in a cross-sectional side view. The device includes a dielectric layer located over the heater component and between the first conductive component and the second conductive component in the cross-sectional side view. The dielectric layer, the first conductive component, and the second conductive component have substantially co-planar upper surfaces in the cross-sectional side view. The device includes a phase change material (PCM) located over the dielectric layer and at least partially over the first conductive component and the second conductive component in the cross-sectional side view. The PCM is in a conductive state or a non-conductive state based on heat generated by the heater component. The device includes a capping layer located over the PCM.

Yet another aspect of the present disclosure pertains to a method. A device is provided. The device includes a first conductive component, a second conductive component, and a heater component, wherein a segment of the heater component is disposed between the first conductive component and the second conductive component in a cross-sectional side view. A patterned photoresist layer is formed over the device. The patterned photoresist layer at least partially covers the first conductive component and the second conductive component. The patterned photoresist layer defines an opening that exposes the segment of the heater component. An etching process is performed to the device while the patterned photoresist layer serves as a protective mask, such that the etching process removes a portion of the segment of the heater component, while portions of the first conductive component and the second conductive component are protected from being etched by the patterned photoresist layer. A dielectric layer is formed over the heater component. The dielectric layer, the first conductive component, and the second conductive component have substantially co-planar upper surfaces in the cross-sectional side view. A phase change material (PCM) is formed over the substantially co-planar upper surfaces of the dielectric layer, the first conductive component, and the second conductive component, such that a bottom surface of the PCM is substantially flat in the cross-sectional side view.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A device, comprising:
a material layer;
a first conductive component and a second conductive component each disposed over the material layer in a cross-sectional side view;
a heater component disposed over the material layer in the cross-sectional side view, wherein a segment of the heater component is disposed between the first conductive component and the second conductive component in the cross-sectional side view and in a planar top view, and wherein an upper surface of the heater component is less elevated vertically than an upper surface of the first conductive component or the second conductive component in the cross-sectional side view; and
a phase change material (PCM) disposed over the segment of the heater component and at least partially over the first conductive component and the second conductive component in the cross-sectional side view, wherein a resistivity of the PCM changes in response to an application of heat, wherein the heat is produced by the heater component.

2. The device of claim 1, wherein an entire bottom surface of the PCM is substantially flat.

3. The device of claim 1, wherein an entire top surface of the PCM is substantially flat.

4. The device of claim 1, wherein the PCM is in direct contact with the first conductive component and the second conductive component.

5. The device of claim 1, further comprising:
insulating materials disposed between the heater component and the first conductive component and between the heater component and the second conductive component in the cross-sectional side view; and
a dielectric layer disposed between the heater component and the PCM in the cross-sectional side view.

6. The device of claim 5, wherein side surfaces of the dielectric layer are in direct contact with the insulating materials, but not with the PCM, in the cross-sectional side view.

7. The device of claim 5, wherein:
a first portion of a bottom surface of the PCM is in direct contact with an upper surface of the dielectric layer;
a second portion of a bottom surface of the PCM is in direct contact with an upper surface of the first conductive component or the second conductive component; and
the first portion of the bottom surface is substantially co-planar with a second portion of the bottom surface of the PCM.

8. The device of claim 1, further comprising a capping layer disposed over the PCM in the cross-sectional side view.

9. The device of claim 8, wherein:
a bottom surface of the capping layer and an upper surface of the PCM form an interface; and
an entirety of the interface is substantially flat.

10. The device of claim 1, wherein the device is an electrical switch in a radio-frequency (RF) circuit.

11. The device of claim 1, wherein:
the material layer contains a dielectric material;
the first conductive component, the second conductive component, and the heater component each contains tungsten; and
the PCM contains germanium telluride.

12. A device, comprising:
a first conductive component, a second conductive component, and a heater component, wherein a segment of the heater component is located between the first conductive component and the second conductive component in a cross-sectional side view and in a planar top view;
a dielectric layer located over the heater component and between the first conductive component and the second conductive component in the cross-sectional side view, wherein the dielectric layer, the first conductive component, and the second conductive component have substantially co-planar upper surfaces in the cross-sectional side view;
a phase change material (PCM) located over the dielectric layer and at least partially over the first conductive component and the second conductive component in the cross-sectional side view, wherein the PCM is in a conductive state or a non-conductive state based on heat generated by the heater component; and
a capping layer located over the PCM.

13. The device of claim 12, wherein:
an entirety of a top surface the PCM is flat; and
an entirety of a bottom surface the PCM is flat.

14. The device of claim 12, wherein:
the segment of the heater component is a middle segment;
the heater component further includes a first end segment and a second end segment;
the PCM spans over the middle segment of the heater component and partially over the first conductive component and the second conductive component in a first horizontal direction in a top view; and
the PCM is located between the first end segment and the second end segment of the heater component in a second horizontal direction in the top view.

15. The device of claim 12, wherein:
the PCM contains germanium telluride;
the PCM reaches a crystal phase when the heat generated by the heater component heats the PCM to a first temperature; and
the PCM reaches an amorphous phase when the heat generated by the heater component heats the PCM to a second temperature different from the first temperature.

16. A method, comprising:
providing a device that includes a first conductive component, a second conductive component, and a heater component, wherein a segment of the heater component is disposed between the first conductive component and the second conductive component in a cross-sectional side view;
forming a patterned photoresist layer over the device, wherein the patterned photoresist layer at least partially covers the first conductive component and the second conductive component, and wherein the patterned photoresist layer defines an opening that exposes the segment of the heater component;
performing an etching process to the device while the patterned photoresist layer serves as a protective mask, such that the etching process removes a portion of the segment of the heater component, while portions of the first conductive component and the second conductive component are protected from being etched by the patterned photoresist layer;
forming a dielectric layer over the heater component, wherein the dielectric layer, the first conductive component, and the second conductive component have substantially co-planar upper surfaces in the cross-sectional side view; and
forming a phase change material (PCM) over the substantially co-planar upper surfaces of the dielectric layer, the first conductive component, and the second conductive component, such that a bottom surface of the PCM is substantially flat in the cross-sectional side view.

17. The method of claim 16, further comprising: forming a capping layer over the PCM;
wherein:
a bottom surface of the capping layer and an upper surface of the PCM form an interface; and
an entirety of the interface is substantially flat.

18. The method of claim 16, wherein:
the heater component is separated from the first conductive component and the second conductive component by an insulating material; and
the etching process partially removes the insulating material at a greater rate than the heater component, such that an upper surface of the heater component is more elevated vertically than the insulating material in the cross-sectional side view after the etching process has been performed.

19. The method of claim 16, wherein:
the patterned photoresist layer further defines additional openings that partially expose the first conductive component or the second conductive component;
the etching process partially removes the first conductive component or the second conductive component exposed by the additional openings, thereby forming a recess in the first conductive component or the second conductive component; and
the forming the dielectric layer includes filling the recess with a portion of the dielectric layer, wherein the portion of the dielectric layer and a remaining portion of the first conductive component or the second conductive component have substantially co-planar upper surfaces.

20. The method of claim 16, wherein:
the heater component generates heat in response to an electrical voltage;
a resistivity of the PCM changes in response to heat generated by the heater component; and
an electrical path between the first conductive component and the second conductive component is switched on or switched off based on a change in the resistivity of the PCM.
